(19) United States
(12) Patent Application Publication
(10) Pub. No.: US 2007/0032384 A1
(43) Pub. Date: Feb. 8, 2007

(54) Structure for improved high critical current densities in YBCO coatings

(75) Inventors: Stephen R. Foltyn, Los Alamos, NM (US); Quanxi Jia, Los Alamos, NM (US); Haiyan Wang, Los Alamos, NM (US)

Correspondence Address: LOS ALAMOS NATIONAL SECURITY, LLC, LOS ALAMOS NATIONAL LABORATORY, PPO. BOX 1663, LC/IP, MS A187, LOS ALAMOS, NM, 87545, US

(73) Assignee: The Regents of the University of California

(21) Appl. No.: 11/189,228

(22) Filed: Jul. 26, 2005

(51) Int. Cl. H01L 39/24

(52) U.S. Cl. 505/473

(57) ABSTRACT

Improvements in critical current capacity for superconducting film structures are disclosed and include the use of, e.g., multilayer high temperature barium-copper oxide structures where individual high temperature barium-copper oxide layers are separated by a thin layer of a metal oxide material such as CeO₂ and the like.

### STATEMENT REGARDING FEDERAL RIGHTS

This invention was made with government support under Contract No. W-7405-ENG-36 awarded by the U.S. Department of Energy. The government has certain rights in the invention.

### FIELD OF THE INVENTION

The present invention relates to composite structures for achieving high critical current densities in superconductive film tapes. Such composite structures involve a multilayer structure or architecture for high critical current superconductive tapes.

### BACKGROUND OF THE INVENTION

Since their initial development, coated conductor research has focused on fabricating increasing lengths of the material, while increasing the overall critical current carrying capacity. Different research groups have developed several techniques of fabricating coated conductors. Regardless of which techniques are used for the coated conductors, the goal of obtaining highly textured superconducting thick films, such as YBa₂Cu₃O₇₋ₓ (YBCO), with high supercurrent carrying capability on metal substrates remains. The use of thick superconducting films for coated conductors appears logical because both the total critical current and the engineering critical current density (defined as the ratio of total critical current and the cross-sectional area of the tape) are directly correlated with the thickness of the superconducting films. It has been known for some time (see, Foltyn et al., Appl. Phys. Lett., 63, 1848-1850, 1993) that the critical current density of a YBCO film is a function of film thickness for films on either single crystal wafers or polycrystalline nickel-based alloy substrates. A higher critical current density is achieved at a YBCO film thickness in the range of about 100 to about 400 nanometers (nm). On the other hand, critical current density tends to decrease with increasing YBCO film thickness. Critical current density is lower for YBCO on polycrystalline metal substrates, mainly due to less superior in-plane texture of the YBCO films. The challenge has been that adding more YBCO material beyond about 2 μm using normal processing conditions on metal substrates does not contribute to the overall supercurrent carrying capability.

U.S. Pat. No. 6,383,989 demonstrated that the Jc of thick films of YBCO could be improved by the use of a multilayer structure involving alternate layers of YBCO and an interlayer material of an insulator such as cerium oxide or a different superconducting material such as samarium-BCO. While both of these interlayer materials helped to raise the J_{c} values (see App. Phys. Lett., 2002 80, pp. 1601-1603), I_{c} values did not exceed several hundred A/cm-width. Additionally, it was determined that the Jc improvement resulted from a film smoothing effect characteristic of the multilayer structure, a characteristic absent in comparable single layer YBCO films. Subsequently, it was determined that the rough substrates in use at that time caused the need for the smoothing. The development of smoother substrates (U.S. patent application Ser. No. 10/624,350, “High Current Density Electropolishing in the Preparation of Highly Smooth Substrate Tapes for Coated Conductors” by Kreiscott et al.). ended the need for the smoothing effect by such multilayers. Another factor in the multilayer structure disclosed in U.S. Pat. No. 6,383,989 was that current could not pass in the z direction of the film, i.e., across the multilayers of cerium oxide and YBCO. This required employing a patterning process to allow current measurements of the different YBCO layers separated by the cerium oxide.

Despite the recent progress in production of superconductive tapes, continued improvements remain desirable in the magnitude of critical current properties.

### SUMMARY OF THE INVENTION

To achieve the foregoing and other objects, and in accordance with the purposes of the present invention, as embodied and broadly described herein, the present invention provides an article including a substrate of a single crystal substrate, an amorphous substrate or a polycrystalline substrate, the substrate including at least one oriented layer thereon; and, a multilayer superconductive structure thereon the at least one oriented layer, the multilayer superconductive structure including at least two layers of a high temperature barium-copper oxide superconducting material, each layer characterized by a thickness of from about 100 nm to about 1000 nm, each pair of layers of the high temperature barium-copper oxide superconducting material separated by a layer of an electrically conductive metal oxide material having chemical and structural compatibility with the high temperature barium-copper oxide superconducting material, the layer of electrically conductive metal oxide material characterized by a thickness from about 3 nm to about 60 nm whereby electrical contact is present in the z-direction through the multilayer superconductive structure, the multilayer superconductive structure characterized as having a total combined thickness of high temperature superconducting material layers of at least about 1 micron and as having an I_{c} of greater than 500 amperes per centimeter-width (A/cm-width). In one embodiment of the invention, the electrically conductive metal oxide material between the layers of the high temperature barium-copper oxide superconducting material is cerium oxide. In another embodiment of the present invention, the layer of high temperature barium-copper oxide superconducting material directly upon the at least one oriented layer has a thickness from about 400 nm to about 800 nm, and the subsequent layers of high temperature barium-copper oxide superconducting material not directly upon the at least one oriented layer have a thickness from about 100 nm to about 400 nm.

In another aspect of the present invention, a process is provided of preparing a high temperature superconducting article characterized as having a total combined thickness of high temperature superconducting material of at least 1.0 microns and as having an I_{c} of greater than 500 amperes per centimeter-width (A/cm-width), the article including a substrate from the group of a single crystal substrate, an amorphous substrate and a polycrystalline substrate, the substrate having at least one oriented layer thereon and a multilayer superconductive structure thereon the at least one oriented layer, the multilayer superconductive structure including at least two layers of a high temperature barium-copper oxide superconducting material, each pair of layers of said high temperature barium-copper oxide superconducting material separated by a layer of an electrically conductive metal oxide material having chemical and structural compatibility with the high temperature barium-copper oxide superconducting material, the process including depositing a layer of a high temperature barium-copper oxide superconducting material on said oriented layer of the substrate at temperatures of from about 740° C. to about 765° C., the high temperature barium-copper oxide superconducting material having a thickness of from about 100 nm to about 1000 nm, depositing a layer of an electrically conductive metal oxide on the first layer of HTS material at temperatures of from about 740° C. to about 765° C., the electrically conductive metal oxide having a thickness of from about 3 nm to about 100 nm, depositing a subsequent layer of an high temperature barium-copper oxide superconducting material on the conductive metal oxide layer at temperatures of from about 740° C. to about 765° C., the high temperature barium-copper oxide superconducting material having a thickness of from about 100 nm to about 1000 nm, and depositing at least one additional pair of layers of CeO₂ and high temperature barium-copper oxide superconducting material onto the subsequent layer of HTS, where the CeO₂ layer of the additional pair is between a prior deposited layer of high temperature barium-copper oxide superconducting material and the high temperature barium-copper oxide superconducting material of the additional pair, at temperatures of from about 740° C. to about 765° C., the high temperature barium-copper oxide superconducting material having a thickness of from about 100 nm to about 1000 nm and the electrically conductive metal oxide having a thickness of from about 3 nm to about 100 nm, whereby a resultant high temperature superconducting article is formed having an I_{c} of greater than 500 amperes per centimeter-width (A/cm-width), such I_{c} values characterized as better than I_{c} values where the depositions of the high temperature barium-copper oxide superconducting material and the electrically conductive metal oxide are conducted at temperatures at or above about 770° C.

### BRIEF DESCRIPTION OF THE DRAWINGS

FIG. 1 shows a generic structure of a composite multilayer YBCO film in accordance with an embodiment of the present invention.

FIG. 2 shows a plot of the current carrying capacity (critical current and current density) of a single layer YBCO film as a function of film thickness.

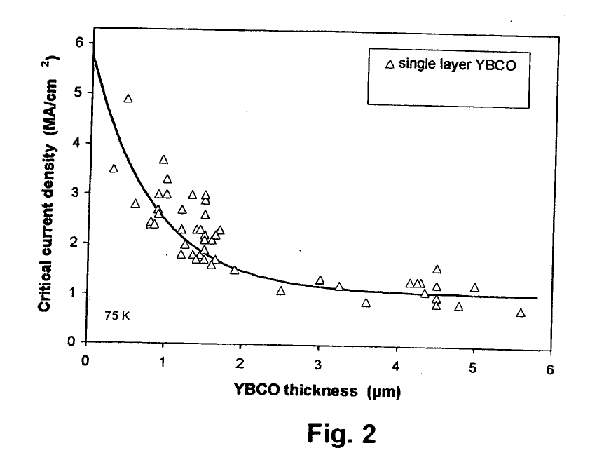

FIG. 3 shows a plot of critical current densities versus total YBCO and CeO₂ thickness for examples having: a single YBCO layer (circles); four YBCO layers separated by cerium oxide interlayers (diamonds); and six YBCO layers separated by cerium oxide interlayers (squares), each on an IBAD-MgO—Ni alloy substrate measured at 75.4 K and self field.

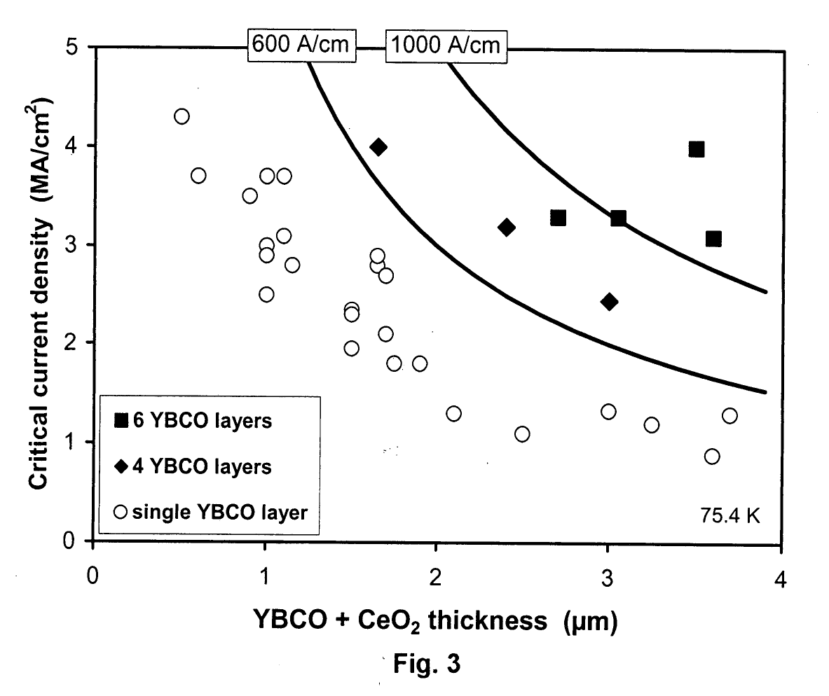

### DETAILED DESCRIPTION

The present invention is concerned with high temperature superconducting wire or tape and the use of high temperature superconducting films to form such wire or tape. In the present invention, the superconducting material is generally a barium copper oxide high temperature superconductor. Numerous rare earth metals are known to form high temperature barium copper oxide superconductors, including, e.g., samarium, dysprosium, erbium, neodymium, europium, holmium, ytterbium, and gadolinium. Yttrium is the preferred metal in forming the high temperature barium copper oxide superconductor (YBCO), e.g., YBa₂Cu₃O_{7-δ}, Y₂Ba₄Cu₇O₁₄₊ₓ, or YBa₂Cu₄O₈, although other minor variations superconducting material may also be used. Combinations of the yttrium and other rare earth metals can be used as the high temperature barium copper oxide superconductors. Other superconducting materials such as bismuth and thallium based superconductor materials may sometimes be employed. YBa₂Cu₃O_{7-δ} is preferred as the superconducting material. Addition of selected particulate materials to the high temperature superconducting material can enhance flux pinning properties. Such particulate materials can be of barium zirconate, yttrium barium zirconate, yttrium oxide and the like. The particulates are preferably sizes from about 5 nanometers to about 100 nanometers in major dimension and are generally present in amounts of from about 1 to about 20 weight percent.

In the high temperature superconducting film of the present invention, the substrate can be, e.g., any amorphous material or polycrystalline material. Polycrystalline materials can include materials such as a metal or a ceramic. Such ceramics can include, e.g., materials such as polycrystalline aluminum oxide or polycrystalline zirconium oxide. Preferably, the substrate can be a polycrystalline metal such as nickel, copper and the like. Alloys including nickel such as various Hastalloy metals are also useful as the substrate as are alloys including copper, vanadium and chromium. The metal substrate on which the superconducting material is eventually deposited should preferably allow for the resultant article to be flexible whereby superconducting articles (e.g., coils, motors or magnets) can be shaped. Other substrates such as rolling assisted biaxially textured substrates (RABiTS) may be used as well. The measure of current carrying capacity is called “critical current” and is abbreviated as I_{c}, measured in Amperes (A), and “critical current density” is abbreviated as J_{c}, measured in Amperes per square centimeter (A/cm²). As a width normalized value, I_{c} can be reported in amperes per centimeter-width (A/cm-width) with width referring to the dimensions of the superconducting material. In this way, values may be more meaningfully compared between different samples.

The present invention is concerned with enhancing the total current carrying capability of a YBCO film for coated conductors. The present invention uses multilayer architecture to remove the limitations of a single layer film used in coated conductors where the critical current does not increase linearly with increasing the film thickness.

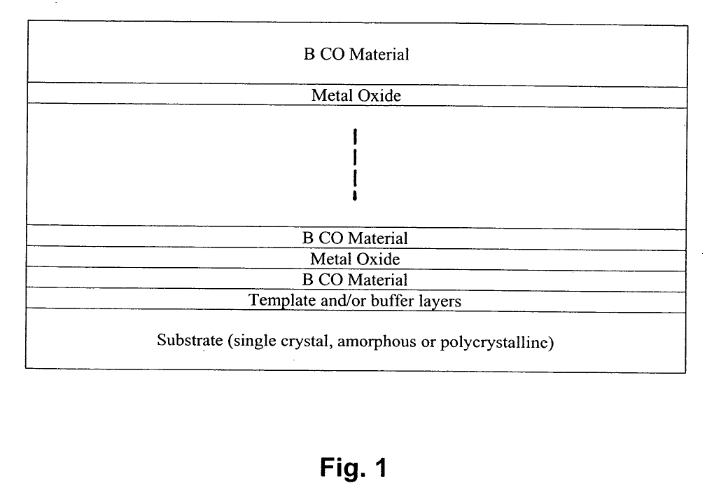

This invention provides an architecture shown in FIG. 1 to enhance the total current carrying capability for a YBCO film. An electrically conductive metal oxide material is used as an interlayer between succeeding superconducting layers, e.g., YBCO layers. This process can be repeated as many times as desired or necessary. This multilayer approach provides more surface area where surface pinning may play additional role in enhancing the critical current of the superconducting films. The metal oxide materials used as interlayers should be chemically and structurally compatible with YBCO, should have electrical conductivity at the thicknesses used in the present invention and can be generally chosen from, e.g., cerium oxide (CeO₂), yttrium oxide (Y₂O₃), strontium titanate (SrTiO₃), strontium ruthenium oxide (SrRuO₃), hafnium oxide (HfO₂), yttria-stabilized zirconia (YSZ), magnesium oxide (MgO), nickel oxide, samarium oxide, europium oxide, lanthanum aluminum oxide (LaAlO₃), lanthanum strontium cobalt oxide (La_{0.5}Sr_{0.5}CoO₃), neodymium copper oxide, cadmium copper oxide, europium copper oxide, and neodymium gadolinium oxide (NdGaO₃). Preferably, the metal oxide material is CeO₂, Y₂O₃, SrRuO₃, or SrTiO₃ and more preferably, the metal oxide material is CeO₂.

The thickness of the metal oxide layers is generally in from about 3 nanometers (nm) to about 60 nm, more preferably from about 5 nanometers to about 60 nanometers, and most preferably from about 5 nanometers to about 40 nanometers. Preferably, the thickness of the metal oxide layers is such that current can pass from the top to bottom of the stack, i.e., in the z-direction through the multilayer superconductive structure thereby eliminating any need for patterning of the various layers to obtain electrical connections throughout the entire film thickness.

The individual layers of YBCO can have a general thickness in the range of about 100 nm (0.1 μm) to about 1000 nm (1 μm), more preferably in the range of from about 100 nm (0.1 μm) to about 600 nm (0.6 μm). In one embodiment, thickness of first layer of YBCO is deposited thicker than subsequent layers of the YBCO. For example, the first YBCO layer can be deposited at a thickness of from about 400 nm (0.4 μm) to about 800 nm (0.8 μm), while subsequent YBCO layers can be deposited at a thickness of from about 100 nm (0.1 μm) to about 400 nm (0.4 μm). The addition of more of the thinner layers of YBCO added to the multilayer architecture can generally result in better I_{c} and J_{c} values. The total thickness of the multilayer film is greater than about 1 μm, preferably greater than about 1.5 μm, and more preferably greater than about 3 μm. The thicknesses may generally range as high as desired, e.g., up to about 10 μm, but are generally from about 2 μm to about 5 μm. Different layers of the multilayer may have different thicknesses for selected applications.

Various combinations of high temperature superconducting barium-copper oxides may be used in the different layers. As previously described, the high temperature superconducting barium-copper oxides can generally include yttrium or any suitable rare earth metal from the periodic table, such as samarium, dysprosium, erbium, neodymium, europium, holmium, ytterbium, and gadolinium. In some instances, the high temperature superconducting barium-copper oxide can include yttrium and one or more of the rare earth metal, or can include two or more of the rare earth metals. Yttrium is a preferred metal in a high temperature superconducting barium-copper oxide to form the well-known YBCO.

Multilayer YBCO films have been deposited on polycrystalline Ni-alloy using MgO deposited by ion beam assisted deposition (IBAD-MgO) as a template. IBAD-YSZ can also be used as a template. A multilayer YBCO/CeO₂/YBCO/CeO₂/YBCO/CeO₂/YBCO structure was deposited on an IBAD-MgO/Ni-alloy substrate, where the thickness of the YBCO layer was about 0.75 μm and the thickness of the CeO₂ layer was about 50 nm. Another multilayer YBCO/CeO₂/YBCO/CeO₂/YBCO/CeO₂YBCO/CeO₂/YBCO/CeO₂/YBCO structure was deposited on an IBAD-MgO/Ni-alloy substrate, where the thickness of the YBCO layer was about 0.55 μm and the thickness of the CeO₂ layer was about 40 nm In both instances, current could be measured across or though the multilayer stack in the z-direction.

The YBCO layer can be deposited, e.g., by pulsed laser deposition or by methods such as evaporation including coevaporation, e-beam evaporation and activated reactive evaporation, sputtering including magnetron sputtering, ion beam sputtering and ion assisted sputtering, cathodic arc deposition, chemical vapor deposition, organometallic chemical vapor deposition, plasma enhanced chemical vapor deposition, molecular beam epitaxy, a sol-gel process, a solution process and liquid phase epitaxy. Post-deposition anneal processes are necessary with some deposition techniques to obtain the desired superconductivity.

In pulsed laser deposition, powder of the material to be deposited can be initially pressed into a disk or pellet under high pressure, generally above about 1000 pounds per square inch (PSI) and the pressed disk then sintered in an oxygen atmosphere or an oxygen-containing atmosphere at temperatures of about 950° C. for at least about 1 hour, preferably from about 12 to about 24 hours. An apparatus suitable for pulsed laser deposition is shown in Appl. Phys. Lett. 56, 578 (1990), “Effects of Beam Parameters on Excimer Laser Deposition of YBa₂Cu₃O_{7-δ}”, such description hereby incorporated by reference.

Suitable conditions for pulsed laser deposition include, e.g., the laser, such as an excimer laser (20 nanoseconds (ns), 248 or 308 nanometers (nm)), targeted upon a rotating pellet of the target material at an incident angle of about 45°. The substrate can be mounted upon a heated holder rotated at about 0.5 rpm to minimize thickness variations in the resultant film or coating, The substrate can be heated during deposition at temperatures from about 600° C. to about 950° C., preferably from about 740° C. to about 765° C. where YBCO is the superconducting material. An oxygen atmosphere of from about 0.1 millitorr (mTorr) to about 10 Torr, preferably from about 100 to about 250 mTorr, can be maintained within the deposition chamber during the deposition. Distance between the substrate and the pellet can be from about 4 centimeters (cm) to about 10 cm. Surprisingly, it has been found that deposition of the multilayer superconducting structure at temperatures from about 740° C. to about 765° C. yields superior results than depositions done at higher temperatures such as above about 775° C. whereat J_{c}'s became diminished upon single crystal substrates.

The deposition rate of the film can be varied from about 0.1 angstrom per second (A/s) to about 200 A/s by changing the laser repetition rate from about 0.1 hertz (Hz) to about 200 Hz. Generally, the laser beam can have dimensions of about 1 millimeter (mm) by 4 mm with an average energy density of from about 1 to 4 joules per square centimeter (J/cm²). After deposition, the films generally are cooled within an oxygen atmosphere of greater than about 100 Torr to room temperature.

The present invention is more particularly described in the following examples which are intended as illustrative only, since numerous modifications and variations will be apparent to those skilled in the art.

### EXAMPLE 1

A multilayer including 4 layers of YBCO and 3 interlayers of cerium oxide (CeO₂) (YBCO/CeO₂YBCO/CeO₂/YBCO/CeO₂/YBCO) was deposited on a nickel metal substrate including a layer of aluminum oxide (Al₂O₃) on the nickel, a layer of yttrium oxide (Y₂O₃) on the Al₂O₃, a layer of magnesium oxide (MgO) deposited on the Y₂O₃ by ion beam assisted deposition (IBAD), a homoepitaxial layer of magnesium oxide upon the IBAD MgO, and a layer of strontium titanate as a buffer layer of the MgO, using pulsed laser deposition under conventional processing conditions, i.e., a substrate temperature of about 700° C. (see, Jia et al., Physica C, v. 228, pp. 160-164, 1994). Each YBCO layer was about 0.75 μm in thickness for a total YBCO thickness of about 3.0 μm. Each CeO₂ layer was about 30 nm. Measured J_{c} was about 2.5 MA/cm².

### EXAMPLE 2

A multilayer including 4 layers of YBCO and 3 interlayers of cerium oxide (CeO₂) (YBCO/CeO₂/YBCO/CeO₂/YBCO/CeO₂/YBCO) was deposited on a nickel metal substrate including a layer of aluminum oxide (Al₂O₃) on the nickel, a layer of yttrium oxide (Y₂O₃) on the Al₂O₃, a layer of magnesium oxide (MgO) deposited on the Y₂O₃ by ion beam assisted deposition (IBAD), a homoepitaxial layer of magnesium oxide upon the IBAD MgO, and a layer of strontium titanate as a buffer layer of the MgO using pulsed laser deposition under conventional processing conditions. Each YBCO layer was about 0.60 μm in thickness for a total YBCO/Y₂O₃ thickness of about 2.5 μm. Each CeO₂ layer was about 30 nm. Measured J_{c} was about 3.2 MA/cm².

### EXAMPLE 3

A multilayer including 4 layers of YBCO and 3 interlayers of cerium oxide (CeO₂) (YBCO/CeO₂/YBCO/CeO₂/YBCO/CeO₂/YBCO) was deposited on a single crystal MgO substrate, including a layer of strontium titanate as a buffer layer of the MgO, using pulsed laser deposition under conventional processing conditions with the exception that a lower substrate temperature of about 760° C. was employed. Each YBCO layer was about 0.55 μm in thickness for a total YBCO thickness of about 2.2 μm. Each CeO₂ layer was about 30 nm. Measured J_{c} was about 4.0 MA/cm².

### EXAMPLE 4

A multilayer including 4 layers of YBCO and 3 interlayers of yttrium oxide (Y₂O₃) (YBCO/Y₂O₃/YBCO/Y₂O₃/YBCO/Y₂O₃/YBCO) was deposited on a single crystal MgO substrate, including a layer of strontium titanate as a buffer layer of the MgO, using pulsed laser deposition under conventional processing conditions with the exception that a lower substrate temperature of about 760° C. was employed. Each YBCO layer was about 0.60 μm in thickness for a total YBCO/Y₂O₃ thickness of about 2.5 μm. Each Y₂O₃ layer was about 30 nm. Measured J_{c} was about 3.5 MA/cm².

### EXAMPLE 5

A multilayer including 6 layers of YBCO and 5 interlayers of cerium oxide (CeO₂) (YBCO/CeO₂/YBCO/CeO₂/YBCO/CeO₂/YBCO/CeO₂/YBCO/CeO₂/YBCO) was deposited on a nickel metal substrate including a layer of aluminum oxide (Al₂O₃) on the nickel, a layer of yttrium oxide (Y₂O₃) on the Al₂O₃, a layer of magnesium oxide (MgO) deposited on the Y₂O₃ by ion beam assisted deposition (IBAD) and a homoepitaxial layer of magnesium oxide upon the IBAD MgO, using pulsed laser deposition under conventional processing conditions (see, Jia et al., Physica C, v. 228, pp. 160-164, 1994). Each YBCO layer was about 0.55 μm in thickness for a total YBCO thickness of about 3.3 μm. Each CeO₂ layer was about 40 nm. The total thickness of the YBCO/ceria multilayer was about 3.5 μm. Measured J_{c} was about 4.0 MA/cm². I_{c} was calculated as about 1400 A/cm-width. For comparison, a single layer of YBCO with a thickness of about 3.7 μm was deposited upon a similar substrate and had a measured J_{c} of about 1.3 MA/cm². Thus, the single layer carried only about a third of the critical current as the multilayer structure.

### EXAMPLE 6

A series of multilayer structures including 2 layers of YBCO and a single interlayer of varying thickness of cerium oxide (CeO₂) (YBCO/CeO₂/YBCO) was deposited on single crystal MgO substrates, including a layer of strontium titanate as a buffer layer on the MgO, using pulsed laser deposition under conventional processing conditions. Each YBCO layer was about 0.60 μm in thickness for a total YBCO/CeO₂ thickness of about 1.2 μm. The CeO₂ layer was varied from about 5 nm to about 50 nm. In each of these example the J_{c} was measured with leads on opposing sides of the multilayer structure such that electrical contact through the cerium oxide layer is established. Measured J_{c}'s are shown in Table 1. It can be seen that thin layers of cerium oxide provide excellent J_{c} values.

TABLE 1

| | | | | | | |
|---|---|---|---|---|---|---|
| CeO₂ thickness | 5 | 10 | 20 | 30 | 40 | 50 |
| (nm) | | | | | | |
| J_{c} (MA/cm²) | 3.0 | 2.9 | 3.6 | 3.3 | 3.5 | 2.9 |

Although the present invention has been described with reference to specific details, it is not intended that such details should be regarded as limitations upon the scope of the invention, except as and to the extent that they are included in the accompanying claims.

What is claimed is:

1. An article comprising:
a substrate selected from the group consisting of a single crystal substrate, an amorphous substrate and a polycrystalline substrate, said substrate including at least one oriented layer thereon; and,
a multilayer superconductive structure thereon said at least one oriented layer, said multilayer superconductive structure including at least two layers of a high temperature barium-copper oxide superconducting material, each layer characterized by a thickness of from about 100 nm to about 1000 nm, each pair of layers of said high temperature barium-copper oxide superconducting material separated by a layer of an electrically conductive metal oxide material having chemical and structural compatibility with said high temperature barium-copper oxide superconducting material, said layer of a metal oxide material characterized by a thickness from about 3 nm to about 60 nm whereby electrical contact is present in the z-direction through the multilayer superconductive structure, said multilayer superconductive structure characterized as having a total combined thickness of high temperature superconducting material layers of at least 1.0 microns and as having an I of greater than 500 amperes per centimeter-width (A/cm-width).

2. The article of claim 1 wherein said electrically conductive metal oxide material is selected from the group consisting of cerium oxide, yttrium oxide, strontium titanate, hafnium oxide, yttria-stabilized zirconia, magnesium oxide, nickel oxide, europium oxide, samarium oxide, neodymium copper oxide, cadmium copper oxide and europium copper oxide.

3. The article of claim 1 wherein said high temperature barium-copper oxide superconducting material is a rare earth barium-copper oxide.

4. The article of claim 1 wherein said electrically conductive metal oxide material has a thickness from about 5 nm to about 50 nm.

5. The article of claim 1 wherein said substrate is an amorphous substrate or a polycrystalline substrate and a layer of said high temperature barium-copper oxide superconducting material from said at least two layers of high temperature barium-copper oxide superconducting material is directly upon said substrate and has a thickness from about 400 nm to about 800 nm.

6. The article of claim 5 wherein said layers of high temperature barium-copper oxide superconducting material not directly upon said substrate have a thickness from about 100 nm to about 600 nm.

7. The article of claim 1 wherein said electrically conductive metal oxide material is cerium oxide.

8. The article of claim 1 wherein said multilayer superconductive structure includes at least three layers of a high temperature superconducting material, each of said layers having a thickness from about 100 nm to about 600 nm.

9. The article of claim 1 wherein said multilayer superconductive structure includes at least four layers of a high temperature superconducting material, each of said layers having a thickness from about 100 nm to about 600 nm.

10. The article of claim 8 wherein said electrically conductive metal oxide material is cerium oxide and each layer of electrically conductive cerium oxide has a thickness from about 5 nm to about 50 nm.

11. The article of claim 1 wherein said multilayer superconductive structure is characterized as having a total combined thickness of high temperature superconducting material layers of at least about 3.0 microns and as having an I_{c} of greater than 1000 amperes per centimeter-width (A/cm-width).

12. The article of claim 3 wherein said rare earth barium copper oxide is yttrium barium copper oxide.

13. The article of claim 3 wherein said rare earth barium copper oxide is yttrium samarium barium copper oxide.

14. The article of claim 1 wherein said at least two layers of a high temperature superconducting material includes layers of differing compositions of rare earth barium copper oxides.

15. The article of claim 1 wherein said layers of a high temperature superconducting material further include flux pinning particulates therein. of barium zirconate.

16. The article of claim 12 wherein said yttrium barium copper oxide further includes flux pinning particulates therein.

17. The article of claim 15 wherein the flux pinning particulates are nanoparticulates of barium zirconate.

18. The article of claim 16 wherein the flux pinning particulates are nanoparticulates of barium zirconate.

19. The article of claim 1 wherein said substrate is a single crystal substrate and a layer of said high temperature barium-copper oxide superconducting material from said at least two layers of high temperature barium-copper oxide superconducting material is directly upon said substrate and has a thickness from about 100 nm to about 600 nm.

20. A process of preparing a high temperature superconducting article characterized as having a total combined thickness of high temperature superconducting material of at least 1.0 microns and as having an I_{c} of greater than 500 amperes per centimeter-width (A/cm-width), the article including a substrate from the group of a single crystal substrate, an amorphous substrate and a polycrystalline substrate, the substrate having at least one oriented layer thereon and a multilayer superconductive structure thereon the at least one oriented layer, the multilayer superconductive structure including at least two layers of a high temperature barium-copper oxide superconducting material, each pair of layers of said high temperature barium-copper oxide superconducting material separated by a layer of an electrically conductive metal oxide material having chemical and structural compatibility with the high temperature barium-copper oxide superconducting material, the process comprising:
depositing a layer of a high temperature barium-copper oxide superconducting material on said oriented layer of the substrate at temperatures of from about 740° C. to about 765° C., the high temperature barium-copper oxide superconducting material having a thickness of from about 100 nm to about 1000 nm;
depositing a layer of an electrically conductive metal oxide on the first layer of HTS material at temperatures of from about 740° C. to about 765° C., the electrically conductive metal oxide having a thickness of from about 3 nm to about 100 nm;
depositing a subsequent layer of an high temperature barium-copper oxide superconducting material on the conductive metal oxide layer at temperatures of from about 740° C. to about 765° C., the high temperature barium-copper oxide superconducting material having a thickness of from about 100 nm to about 1000 nm; and,
depositing at least one additional pair of layers of CeO and high temperature barium-copper oxide superconducting material onto the subsequent layer of HTS, where the CeO layer of the additional pair is between a prior deposited layer of high temperature barium-copper oxide superconducting material and the high temperature barium-copper oxide superconducting material of the additional pair, at temperatures of from about 740° C. to about 765° C., the high temperature barium-copper oxide superconducting material having a thickness of from about 100 nm to about 1000 nm and the electrically conductive metal oxide having a thickness of from about 3 nm to about 100 nm, whereby a resultant high temperature superconducting article is formed having an I_{c} of greater than 500 amperes per centimeter-width (A/cm-width), such I_{c} values characterized as better than I_{c} values where the depositions of the high temperature barium-copper oxide superconducting material and the electrically conductive metal oxide are conducted at temperatures at or above about 770° C.
